(19) United States
(12) Patent Application Publication
(10) Pub. No.: US 2010/0325520 A1
(43) Pub. Date: Dec. 23, 2010

(54) RADIO COMMUNICATION DEVICE AND REPETITION METHOD

(76) Inventors: Kenichi Kuri, Kanagawa (JP); Akihiko Nishio, Kanagawa (JP); Katsuhiko Hiramatsu, Leuven (BG)

Correspondence Address: Dickinson Wright PLLC;James E. Ledbetter, Esq., International Square, 1875 Eye Street, N.W., Suite 1200, Washington, DC, 20006, US

(21) Appl. No.: 12/526,415

(22) PCT Filed: Feb. 8, 2008
(86) PCT No.: PCT/JP2008/000184

§ 371 Date: Aug. 7, 2009

(30) Foreign Application Priority Data
Feb. 9, 2007 (JP) 2007-030648

(51) Int. Cl. H03M 13/05; G06F 11/10

(52) U.S. Cl. 714/758; 714/752; 714/E11.032

(57) ABSTRACT

Provided is a radio communication device which can obtain the maximum improvement effect of the error rate characteristic by repletion when an LDPC code is used as an error correction code. In this device, an LDPC encoding unit (101) performs LDPC encoding on a transmission bit string by using an inspection matrix so as to obtain an LDPC code word formed by a systematic bit and a parity bit and output it to a repletion unit (102) and output the inspection matrix to the repetition unit (102). The repetition unit (102) performs repetition in the ascending order of the column weight of the inspection matrix in the LDPC code word and if a plurality of bits have the same column weight, in the ascending order of the column weight of the inspection matrix of the check node connected to a variable node corresponding to the bit.

### TECHNICAL FIELD

The present invention relates to a radio communication apparatus and repetition method.

### BACKGROUND ART

In recent years, multimedia communication such as data communication and video communication has continued to increase in popularity. Therefore, data sizes are expected to increase even more in the future, and growing demands for higher-speed data rates for mobile communication services are also anticipated.

Then, a fourth-generation mobile communication system called “IMT-Advanced” has been studied by the ITU-R (International Telecommunication Union Radio Communication Sector), and an LDPC (Low-Density Parity-Check) code becomes a focus of attention as error correcting code for implementing a downlink speed of up to 1 Gbps. Use of an LDPC code as an error correcting code enables decoding processing to be parallelized, allowing decoding processing to be speeded up compared with the use of a turbo code that requires iterative serial execution of decoding processing.

LDPC encoding is performed using a parity check matrix where a large number of 0s and a small number of 1s are arranged. A radio communication apparatus of the transmitting side encodes a transmission bit sequence using a parity check matrix, to obtain an LDPC codeword composed of systematic bits and parity bits. A radio communication apparatus of the receiving side decodes received data by iteratively executing passing of the likelihoods of individual bits in the row direction of the parity check matrix and in the column direction of the parity check matrix, to acquire a received bit sequence. Here, the number of 1s contained in each column in a parity check matrix is called the column degree, and the number of 1s contained in each row in a parity check matrix is called the row degree. A parity check matrix can be represented by a Tanner graph, which is a two-part graph composed of rows and columns. In a Tanner graph, each row in a parity check matrix is called a check node, and each column in a parity check matrix is called a variable node. Variable nodes and check nodes of a Tanner graph are connected in accordance with the arrangement of 1s in the parity check matrix, and a radio communication apparatus of the receiving side decodes received data by iteratively executing passing of likelihoods between connected nodes, to obtain a received bit sequence.

A Repetition is a method of setting a lower coding rate than the coding rate of an LDPC code (hereinafter referred to as “mother coding rate”). Repetition is a technique of duplicating (repeating) specific bits in a codeword, to generate a plurality of identical bits. This enables a lower coding rate than the mother coding rate to be set. Further, the receiving side can obtain diversity effect by combining those identical bits.

As a conventional technique of repetition for an LDPC codeword, repeating bits in ascending order from a parity bit having a smaller column degree is studied (see Patent Document 1). Patent Document 1: Japanese Patent Application Laid-Open No. 2005-39585

### DISCLOSURE OF INVENTION

### Problems to be Solved by the Invention

However, above conventional technique does not investigate as to from which parity bit to start repetition when there are a plurality of parity bits having the same column degree. In LDPC encoding, error rate performances vary according to the size of a row degree as well as based on the size of a column degree. Consequently, optimal error rate performances may not be obtained if repetition is performed focusing on column degrees only as in the above conventional technique.

It is therefore an object of the present invention to provide a radio communication apparatus and repetition method that can maximize the effect of improving error rate performances by repetition when an LDPC code is used as an error correcting code.

### Means for Solving the Problem

The radio communication apparatus of the present invention adopts the configuration including: an encoding section that performs low density parity check encoding for a transmission bit sequence using a parity check matrix, to acquire a codeword composed of systematic bits and parity bits; and a repetition section that repeats a bit in the codeword in order from a bit of a smallest column degree in the parity check matrix, and, when there are a plurality of bits of a same column degree, repeats the bit in order from the bit corresponding to a variable node connected with a check node of a smallest row degree in the parity check matrix.

### ADVANTAGEOUS EFFECTS OF INVENTION

According to the present invention, it is possible to maximize the effect of improving error rate performances by repetition when an LDPC code is used as an error correcting code,

### BRIEF DESCRIPTION OF DRAWINGS

FIG. 1 is a block diagram showing a configuration of the radio communication apparatus of the transmitting side according to Embodiment 1 of the present invention;

FIG. 2 is a parity check matrix according to Embodiment 1 of the present invention;

FIG. 3 is a Tanner graph according to Embodiment 1 of the present invention;

FIG. 4 illustrates repetition processing according to Embodiment 1 of the present invention;

FIG. 5 is a block diagram showing a configuration of the radio communication apparatus of the receiving side according to Embodiment 1 of the present invention;

FIG. 6 illustrates combining processing according to Embodiment 1 of the present invention;

FIG. 7 is a parity check matrix according to Embodiment 2 of the present invention;

FIG. 8 is a Tanner graph according to Embodiment 2 of the present invention;

FIG. 9 illustrates repetition processing according to Embodiment 2 of the present invention;

FIG. 10 is a parity check matrix according to Embodiment 3 of the present invention;

FIG. 11 is a Tanner graph according to Embodiment 3 of the present invention;

FIG. 12 illustrates repetition processing according to Embodiment 3 of the present invention;

FIG. 13 is a parity check matrix according to Embodiment 4 of the present invention;

FIG. 14 is a Tanner graph according to Embodiment 4 of the present invention; and

FIG. 15 illustrates repetition processing according to Embodiment 4 of the present invention.

### BEST MODE FOR CARRYING OUT THE INVENTION

Now, embodiments of the present invention will be described in detail with reference to the accompanying drawings.

In the following description, bits generated by repetition will be called “repetition bits.”

### Embodiment 1

In the present embodiment, in a case where there are a plurality of systematic bits having the same column degree in a parity check matrix, systematic bits are repeated in order from the systematic bit corresponding to the variable node connected with the check node having the smallest row degree in the parity check matrix.

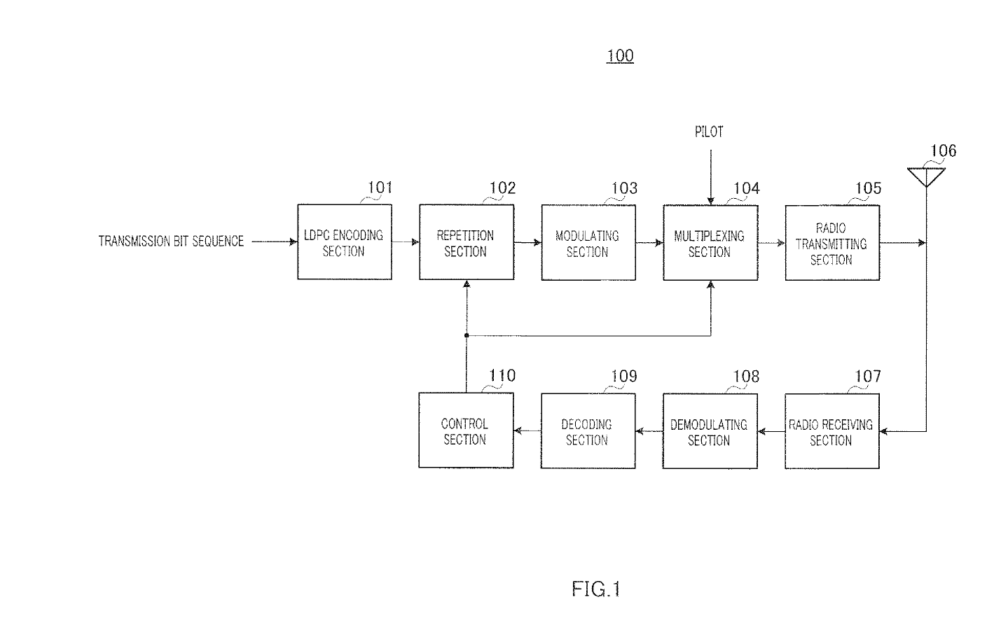

FIG. 1 shows the configuration of radio communication apparatus 100 of the transmitting side according to the present embodiment.

In radio communication apparatus 100 of the transmitting side, LDPC encoding section 101 receives a transmission bit sequence as input. LDPC encoding section 101 performs LDPC encoding on the transmission bit sequence using a parity check matrix to acquire a LDPC codeword composed of systematic bits and parity bits. This LDPC codeword is outputted to repetition section 102. Further, LDPC encoding section 101 outputs the parity check matrix to repetition section 102.

Repetition section 102 repeats the systematic bits in the LDPC codeword, and outputs the LDPC codeword after repetition including repetition bits to modulating section 103. The number of systematic bits to repeat is determined based on the difference between the coding rate in LDPC encoding section 101 (i.e. the mother coding rate) and the coding rate set up from control section 110 (i.e. the coding rate of the LDPC codeword after repetition). To be more specific, the number of systematic bits to repeat is determined by N((Rm/R)−1). Here, N represents the LDPC codeword length, Rm represents the mother coding rate and R represents the coding rate received as input from control section 110. The repetition processing in repetition section 102 will be described later in detail.

Modulating section 103 generates data symbols by modulating the LDPC codeword after repetition, and outputs the generated data symbols to multiplexing section 104.

Multiplexing section 104 multiplexes the data symbols, pilot signals and control signals received as input from control section 110, and outputs the generated multiplexed signal to radio transmitting section 105.

Radio transmitting section 105 performs transmitting processing including D/A conversion, amplification and up-conversion on the multiplexed signal, and transmits the signal after transmitting processing to a radio communication apparatus of the receiving side from antenna 106.

Meanwhile, radio receiving section 107 receives the control signal transmitted from the radio communication apparatus of the receiving side through antenna 106, performs receiving processing such as down-conversion and A/D conversion on the control signal and outputs the control signal to demodulating section 108. This control signal includes a CQI (Channel Quality Indicator) generated in the radio communication apparatus of the receiving side.

Demodulating section 108 demodulates the control signal and outputs the demodulated signal to decoding section 109.

Decoding section 109 decodes the control signal and outputs the CQI included in the control signal to control section 110.

Control section 110 controls the coding rate of the LDPC codeword after repetition, according to the CQI. Control section 110 determines a coding rate corresponding to the CQI received as input, and outputs a control signal showing the determined coding rate to repetition section 102 and multiplexing section 104. When the CQI received as input corresponds to lower channel quality, control section 110 determines the coding rate of the LDPC codeword after repetition to be a lower coding rate.

Next, the repetition processing in repetition section 102 will be described in detail.

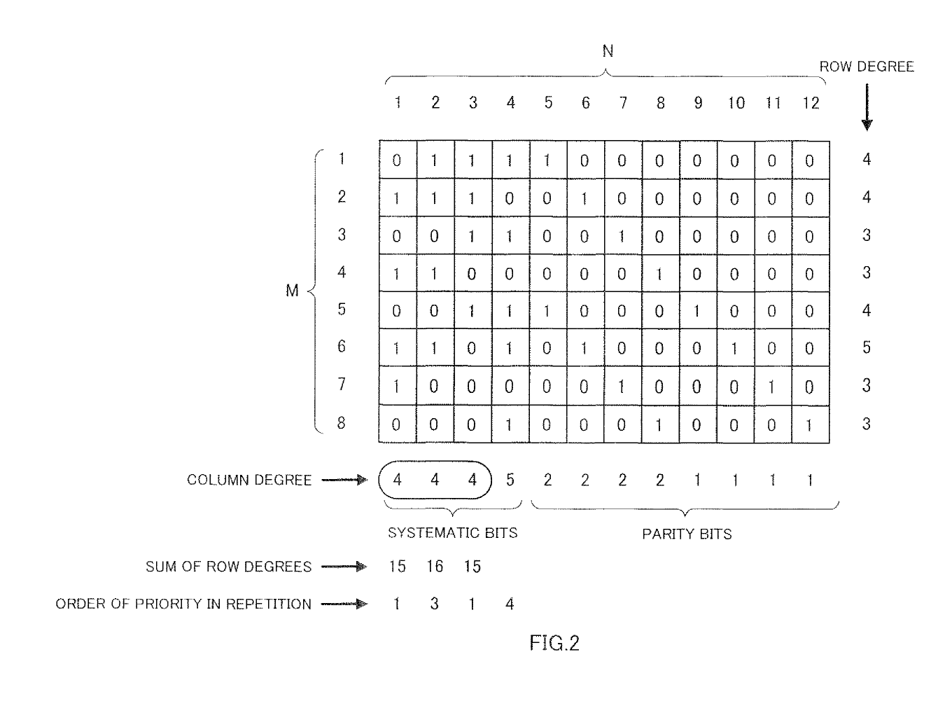

FIG. 2 shows an 8×12 parity check matrix as an example. As shown here, a parity check matrix is represented by a M×N matrix and is composed of 0s and 1s.

Each column in a parity check matrix corresponds to bits in the LDPC codeword. That is, when LDPC encoding is performed using the parity check matrix shown in FIG. 2, a 12-bit LDPC codeword is acquired.

Further, in the parity check matrix shown in FIG. 2, the column degree of the first column is the number of is in the first column, that is, four, and the column degree of the second column is the number of 1s in the second column, that is, four. Therefore, in the 12-bit LDPC codeword, the column degree of the first bit is four and the column degree of the second bit is four. The same will apply to the third to twelfth column.

Likewise, in the parity check matrix shown in FIG. 2, the row degree of the first row is the number of is in the first row, that is, four, and the row degree of the second row is the number of 1s in the second row, that is, four. The same will apply to the third to eighth row.

Furthermore, the parity check matrix shown in FIG. 2 can be represented by a Tanner graph composed of the rows and columns of the parity check matrix.

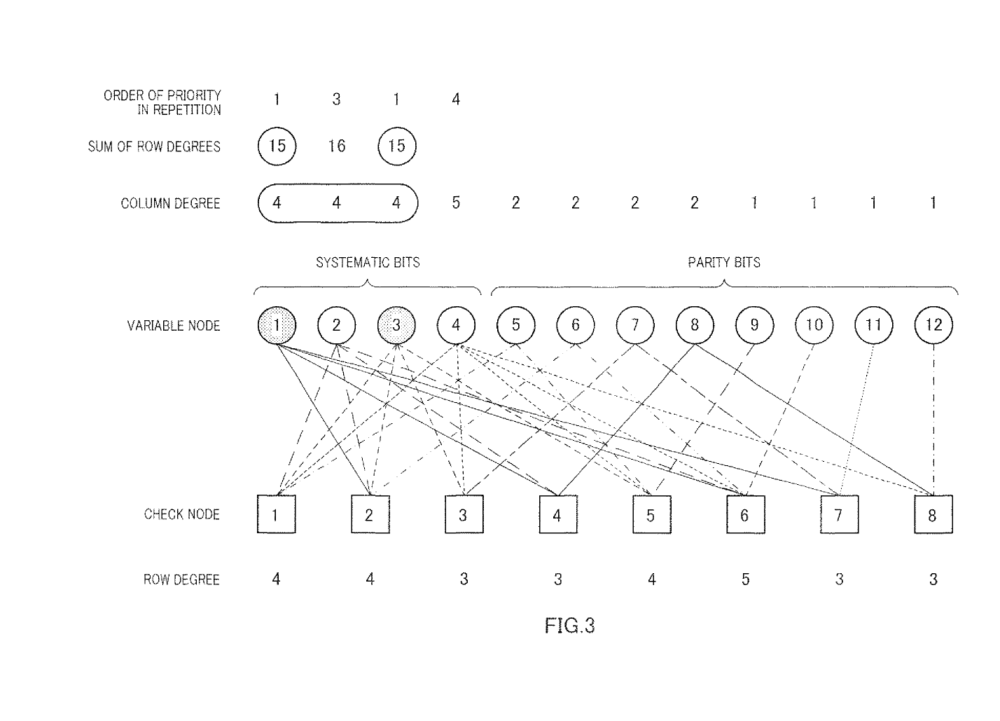

FIG. 3 shows a Tanner graph corresponding to the parity check matrix in FIG. 2. The Tanner graph is composed of check nodes corresponding to rows in a parity check matrix and variable nodes corresponding to columns in a parity check matrix. That is, the Tanner graph corresponding to an 8×12 parity check matrix is a two-part graph composed of eight check nodes and twelve variable nodes.

Furthermore, variable nodes in the Tanner graph correspond to bits in the LDPC codeword.

Here, the variable nodes and check nodes in the Tanner graph are connected in accordance with the arrangement of “1”s in the parity check matrix.

Specific explanation will be given based on the variable nodes. Variable node I in the Tanner graph shown in FIG. 3 corresponds to the first column (N=1) of the parity check matrix shown in FIG. 2. The column degree of the first column of the parity check matrix is four, and the rows in which a 1 is located in the first column are the second row, fourth row, sixth row and seventh row. Therefore, there are four connections from variable node 1, that is, check node 2, check node 4, check node 6 and check node 7. Likewise, variable node 2 in the Tanner graph corresponds to the second column (N=2) of the parity check matrix. The column degree of the second column of the parity check matrix is four, and the rows in which a 1 is located in the second column are the first row, second row, fourth row and sixth row. Therefore, there are four connections from variable node 2, that is, check node 1, check node 2, check node 4 and check node 6. The same will apply to variable node 3 to variable node 12.

Similarly, to give a concrete description based on check nodes, check node 1 of the Tanner graph shown in FIG. 3 corresponds to the first row (M=1) of the parity check matrix shown in FIG. 2. The row degree of the first row of the parity check matrix is four, and the columns in which a 1 is located in the first row are the second column, third column, fourth column and fifth column. Therefore, there are four connections from check node 1, that is, for variable node 2, variable node 3, variable node 4 and variable node 5. Likewise, check node 2 in the Tanner graph corresponds to the second row (M=2) of the parity check matrix. The row degree of the second row of the parity check matrix is four, and the column in which a 1 is located in the second row is the first column, second column, third column and sixth column. Therefore, there are four connections from check node 2, that is, for variable node 1, variable node 2, variable node 3 and variable node 6. The same applies to check node 3 to check node 8.

In this way, in a Tanner graph, the variable nodes and check nodes are connected in accordance with the arrangement of 1s in a parity check matrix. That is, the number of check nodes connected to each variable node in a Tanner graph equals the column degree of a column in a parity check matrix. Also, the check nodes with which each variable node is connected in a Tanner graph are the check nodes corresponding to the rows in which 1s are located in the columns in a parity check matrix. Likewise, the number of variable nodes connected to each check node in a Tanner graph equals the row degree of a row in a parity check matrix. Also, the variable nodes with which each check node is connected in a Tanner graph are the variable nodes corresponding to the column in which 1s are located in the rows in a parity check matrix.

The radio communication apparatus of the receiving side passes likelihoods between the variable nodes, through the check nodes, and decodes received data by iteratively updating the likelihoods of the variable nodes. By this means, the number of times to pass likelihoods between variable nodes decreases when a check node has a smaller number of connections with variable nodes (i.e. when a check node has a smaller row degree). By this means, the number of likelihoods to receive via check nodes which a variable node connects with decreases when the variable node connected with the check node having the smaller number of connections with variable nodes, and therefore the effect of updating likelihoods by an LDPC code is less. That is, in the case where a variable node is repeated, it is preferable to compensate and improve likelihoods by repeating a variable node connected with a check node having the smaller number of connections with variable nodes with priority. That is, the effect of likelihood improving by repetition is greater at a variable node connected with the check node having the smallest number of connections with variable nodes.

Then, in a case where there are a plurality of systematic bits having the same column degree in a LDPC codeword, repetition section 102 repeats the systematic bits in order from the systematic hit corresponding to the variable node connected with the check node holding connections with the smallest number of variable nodes, that is, in order from the systematic bit corresponding to the variable node connected with the check node having the smallest row degree.

Now, a specific explanation will be given below. In the following explanation, the transmission bit sequence length is four bits and the mother coding rate Rm is ⅓. Further, the coding rate R determined in control section 110 is 2/7. That is, when LDPC encoding section 101 performs LDPC encoding on a 4-bit transmission sequence using the parity check matrix shown in FIG. 2, N=12-bit LDPC codeword composed of four systematic bits and eight parity bits is acquired. Further, repetition section 102 derives the number of systematic bits to repeat from N((Rm/R)−1) and repeats two systematic bits, to obtain a 14-bit LDPC codeword including two repetition bits.

First, repetition section 102 extracts the systematic bits to be repetition candidates in order from the systematic bit corresponding to the variable node having the smallest column degree in the parity check matrix (i.e. the systematic bit corresponding to the variable node holding connections with the smallest number of check nodes). That is, repetition section 102 extracts the first to third column (variable node 1 to variable node 3 in the Tanner graph shown in FIG. 3) which have the smallest column degree, 4, and which have the same column degree, as repetition candidates, amongst the first to fourth column corresponding to systematic bits in the parity check matrix shown in FIG. 2 (variable node 1 to variable node 4).

While the number of systematic bits to repeat in repetition section 102 is two, the number of columns to extract, that is, the number of variable nodes holding connections with the same number of check nodes is three, as shown in FIG. 2.

Then, repetition section 102 extracts the systematic bits to be repetition candidates in order from the systematic bit corresponding to the variable node connected with the check node having the smallest row degree in the parity check matrix (i.e. the systematic bit corresponding to the variable node connected with the check node holding connections with the smallest number of variable nodes).

To be more specific, amongst the first column to third column in the parity check matrix shown in FIG. 2, repetition section 102 compares: the sum of the row degrees in the first column, 15, which is a total of the row degree of the second row, four, in which a 1 is located in the first column (i.e. the number of connections, four, with variable nodes in check node 2 which variable node 1 is connected with), the row degree of the fourth row, three (i.e. the number of connections, three, with variable nodes in check node 4 which variable node 1 is connected with), the row degree of the sixth row, five (i.e. the number of connections, five, with variable nodes in check node 6 which variable node 1 is connected with) and the row degree of the seventh row, three (i.e. the number of connections, three, with variable nodes in check node 7 which variable node 1. is connected with), the sum of the row degrees in the second column, 16, which is a total of the row degree of the first row, four, in which a 1 is located in the second column (i.e. the number of connections, four, with variable nodes in check node 1 which variable node 2 is connected with), the row degree of the second row, four (i.e. the number of connections, four, with variable nodes in check node 2 which variable node 2 is connected with), the row degree of the fourth row, three (i.e. the number of connections, three, with variable nodes in check node 4 which variable node 2 is connected with), and the row degree of the sixth row, five (i.e. the number of connections, five, with variable nodes in check node 6 which variable node 2 is connected with), and the sum of the row degrees in the third column, 15, which is a total of the row degree of the first row, four, in which a 1 is located in the third column (i.e. the number of connections, four, with variable nodes in check node 1 which variable node 3 is connected with), row degree of the second row, four (i.e. the number of connections, four, with variable nodes in check node 2 which variable node 3 is connected with), row degree of the third row, three (i.e. the number of connections, three, with variable nodes in check node 2 which variable node 3 is connected with) and the row degree of the fifth row four (i.e. the number of connections, four, with variable nodes in check node 5 which variable node 3 is connected with). That is, repetition section 102 compares the number of connections with variable nodes, between check nodes connected with each variable node amongst variable node 1 to variable node 3 in the Tanner graph shown in FIG. 3. Then, repetition section 102 extracts the systematic bits to be repetition candidates in order from the column corresponding to the smallest row degree (i.e. from the variable node connected with the check node holding connections with the smallest number of variable nodes).

Consequently, the order of priority in repetition amongst the first to fourth column (variable node 1 to variable node 4) is that, as shown in FIGS. 2 and 3, the first column (variable node 1) and third column (variable node 3) are the first, the second column (variable node 2) the third, the fourth column (variable node 4) the fourth.

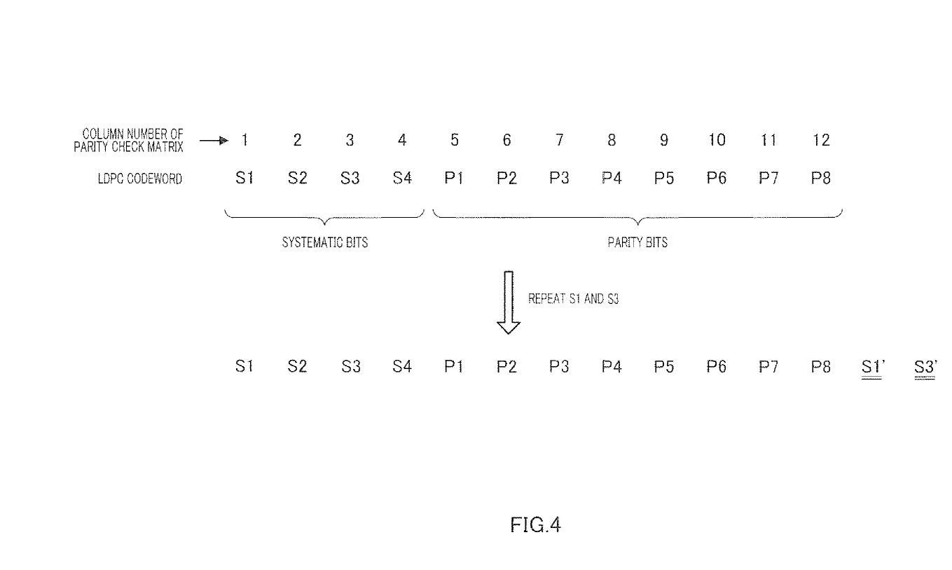

Then, given that the number of systematic bits to repeat is two, repetition section 102 repeats systematic bit Si in the first column (variable node 1) and systematic bit S3 in the third column (variable node 3) in a 12-bit LDPC codeword composed of four systematic bits of S1 to S4 and eight parity bits of P1 to P8, to generate repetition bits S1′ and S3′ as shown in FIG. 4, according to the order of priority in repetition. Repetition bit S1′ is the same as systematic bit SI, and repetition bit S3′ is the same as systematic bit S3. Repetition section 102 inserts S1′ and S3′ in the tail of the LDPC codeword, that is, behind parity bit P8 in order from S1′ to S3′. By this means, repetition section 102 can obtain a 14-bit LDPC codeword composed of four systematic bits of S1 to S4, eight parity bits of P1 to P8 and two repetition bits of S1′ and S3′.

In this way, according to the present embodiment, in a case where there are a plurality of systematic bits having the same column degree in a parity check matrix, systematic bits are repeated in order from the systematic bit corresponding to the variable node connected with the check node having the smallest row degree in the parity check matrix. For this reason, it is possible to repeat systematic bits having little effect on likelihood improving by an LDPC code with priority. By this means, repetition makes it possible to compensate for the likelihoods of systematic bits having little effect on likelihood improving, so that it is possible to make likelihoods of all systematic bits high. Therefore, according to the present invention, it is possible to maximize the effect of improving error rate performances by repetition with an LDPC code.

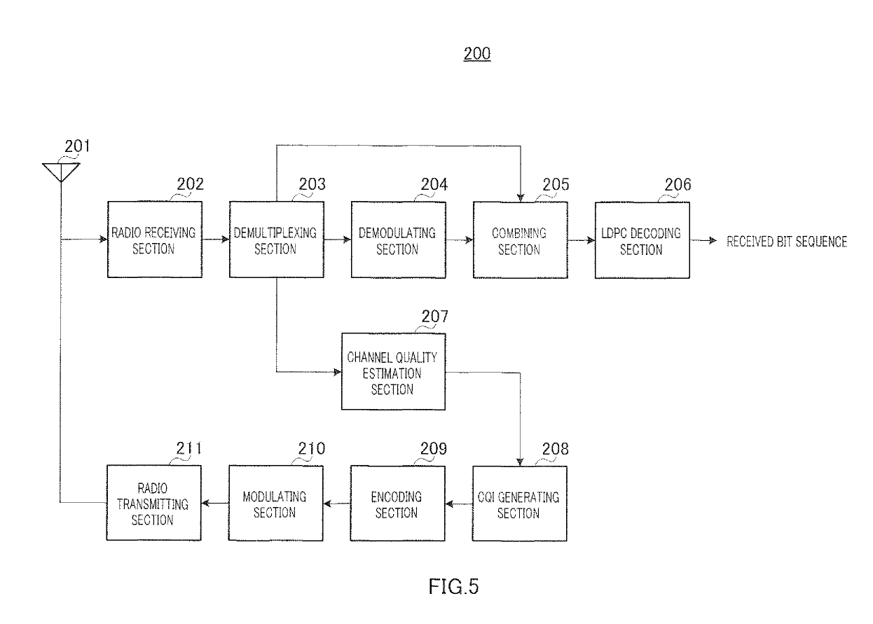

Next, the radio communication apparatus of the receiving side according to the present embodiment will be described. FIG. 5 shows the configuration of radio communication apparatus 200 of the receiving side according to the present embodiment.

In radio communication apparatus 200 of the receiving side, radio receiving section 202 receives a multiplexed signal transmitted from radio communication apparatus 100 (FIG. 1) of the transmitting side through antenna 201, performs receiving processing including down-conversion and A/D conversion on the received signal and outputs the signal subjected to receiving processing to demultiplexing section 203. This received signal includes data symbols, pilot signals and control signals designating coding rates determined in radio communication apparatus 100 of the transmitting side.

Demultiplexing section 203 demultiplexes the received signal into the data symbols, the pilot signals and the control signals. Then, demultiplexing section 203 outputs the data symbols to demodulating section 204, the pilot signals to channel quality estimation section 207 and the control signals to combining section 205.

Demodulating section 204 demodulates the data symbols to acquire received data and outputs the received data to combining section 205.

In the received data, combining section 205 combines bits of the repeated source and repetition bits corresponding to the bits of the repeated source, and outputs the acquired received data to LDPC decoding section 206. The number of repetition bits to combine is determined based on the difference between the coding rate in LDPC decoding section 206, that is, the coding rate Rm in LDPC encoding section 101 (FIG. 1) (i.e. the mother coding rate), and the coding rate R shown by the control signal received as input from demultiplexing section 203 (i.e. coding rate determined in control section 110 (FIG. 1)). To be more specific, the number of repetition bits to combine is determined by Nr(1−(R/Rm)). Here, Nr represents the data length of received data. That is, the number of repetition bits to combine equals the number of systematic bits to repeat in radio communication apparatus 100 (FIG. 1) of the transmitting side. The combining processing in combining section 205 will be described later in detail.

LDPC decoding section 206 performs LDPC decoding on the received data received as input from combining section 205 to acquire a received bit sequence, using the same parity check matrix as the parity check matrix used in LDPC encoding section 101 (FIG. 1).

Meanwhile, channel quality estimation section 207 estimates channel quality using the pilot signal received as input from demultiplexing section 203. Here, channel quality estimation section 207 estimates the SINR (Signal to Interference and Noise Ratio) of the pilot signal as channel quality, and outputs the estimated SINR to CQI generating section 208.

CQI generating section 208 generates a CQI corresponding to the SINR received as input, and outputs the generated CQI to encoding section 209.

Encoding section 209 encodes the CQI and outputs the coded CQI to modulating section 210.

Modulating section 210 modulates the CQI to generate a control signal, and outputs the generated control signal to radio transmitting section 211.

Radio transmitting section 211 performs transmitting processing including D/A conversion, amplification and up-conversion on the control signal and transmits the signal after transmitting processing to radio communication apparatus 100 (FIG. 1) of the transmitting side from antenna 201.

Next, the combining processing in combining section 205 will be described in detail.

Similar to repetition section 102 (FIG. 1) of radio communication apparatus 100 of the transmitting side, in the case where a plurality of systematic bits having the same column degree in received data, combining section 205 combines systematic bits and repetition bits in order from the systematic bit corresponding to the variable node connected with the check node having the smallest row degree (i.e. the check node holding connections with the smallest number of the variable nodes).

Here, the received data length Nr is fourteen bits, the coding rate R represented by a control signal received as input from demultiplexing section 203 is 2/7, and the mother coding rate Rm is ⅓, so that combining section 205 derives the number of repetition bits to combine from Nr(1−(R/Rm)) and combines two repetition bits.

Similar to repetition section 102 (FIG. 1), combining section 205 extracts the first to third column (variable node 1 to variable node 3 in the Tanner graph shown in FIG. 3) which have the smallest column degree, 4, and which have the same column degree, amongst the first to fourth column (variable node 1 to variable node 4) corresponding to the systematic bits in the parity check matrix shown in FIG. 2.

However, while the number of repetition bits to combine in combining section 205 is two, the number of columns to extract, that is, the number of variable nodes holding connections with the same number of check nodes, is three as shown in FIG. 2.

Then, combining section 205 extracts the systematic bits to be combined candidates in order from the systematic bit corresponding to the variable node connected with check node having the smallest row degree (i.e. the check node holding connections with the smallest number of variable nodes) in the parity check matrix.

To be more specific, amongst the first column to third column in the parity cheek matrix shown in FIG. 2, combining section 205 compares: the sum of the row degrees in the first column, 15, which is a total of the row degree of the second row, four, in which a 1 is located in the first column (i.e. the number of connections, four, with variable nodes in check node 2 which variable node 1 is connected with), the row degree of the fourth row, three (i.e. the number of connections, three, with variable nodes in check node 4 which variable node 1 is connected with), the row degree of the sixth row, five (i.e. the number of connections, five, with variable nodes in check node 6 which variable node 1 is connected with) and the row degree of the seventh row, three (i.e. the number of connections, three, with variable nodes in check node 7 which variable node 1 is connected with), the sum of the row degrees in the second column, 16, which is a total of the row degree of the first row, four, in which a 1 is located in the second column (i.e. the number of connections, four, with variable nodes in check node 1 which variable node 2 is connected with), the row degree of the second row, four (i.e. the number of connections, four, with variable nodes in check node 2 which variable node 2 is connected with), the row degree of the fourth row, three (i.e. the number of connections, three, with variable nodes in check node 4 which variable node 2 is connected with), and the row degree of the sixth row, five (i.e. the number of connections, five, with variable nodes in check node 6 which variable node 2 is connected with), and the sum of the row degrees in the third column, 15, which is a total of the row degree of the first row, four, in which a 1 is located in the third column (i.e. the number of connections, four, with variable nodes in check node 1 which variable node 3 is connected with), the row degree of the second row, four (i.e. the number of connections, four, with variable nodes in check node 2 which variable node 3 is connected with), the row degree of the third row, three (i.e. the number of connections, three, with variable nodes in check node 3 which variable node 3 is connected with), and the row degree of the fifth row, four (i.e. the number of connections, four, with variable nodes in check node 5 which variable node 3 is connected with). That is, combining section 205 compares the number of connections with variable nodes between check nodes connected with each variable node amongst variable node 1 to variable node 3 in the Tanner graph shown in FIG. 3. Then, combining section 205 extracts the systematic bits to be combined candidates in order from the column corresponding to the smallest row degree (i.e. from the variable node connected with the check node holding connections with the smallest number of variable nodes).

Consequently, the order of priority in combining amongst the first to fourth column (variable node 1 to variable node 4) is that, as shown. in FIGS. 2 and 3, the first column (variable node 1) and third column (variable node 3) are the first, the second column (variable node 2) the third, the fourth column (variable node 4) the fourth.

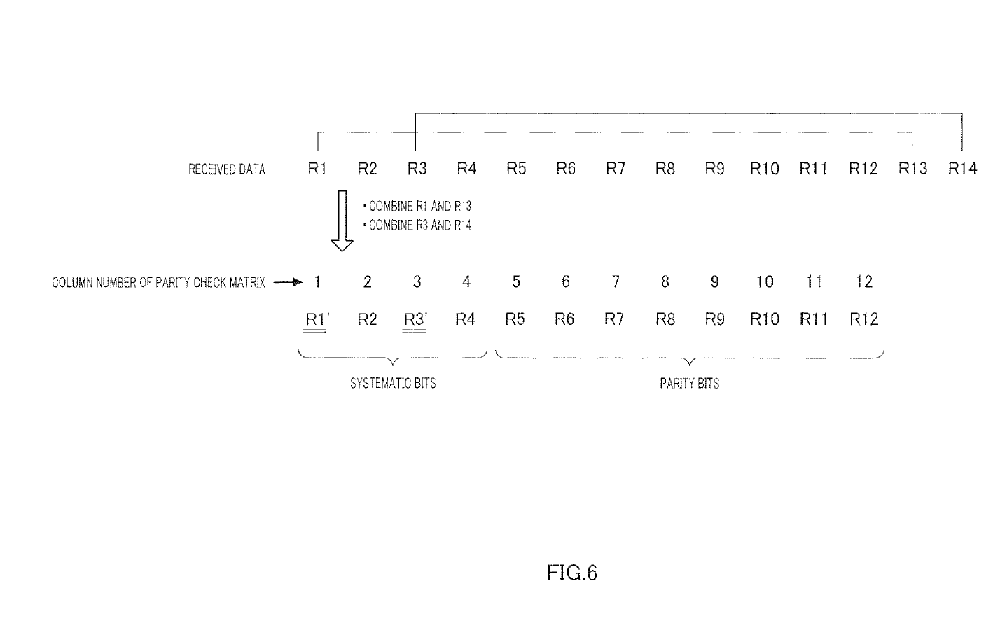

Then, given that the number of repetition bits to combine is two, in a 14-bit received data composed of bits R1 to R14, combining section 205 combines systematic bit R1 in the first column (variable node 1) and repetition bit R13 corresponding to systematic bit R1, to generate R1′, and combines systematic bit R3 in the third column (variable node 3) and repetition bit R14 corresponding to systematic bit R3, to generate R3′, according to the order of priority in combining, as shown in FIG. 6. By this means, the first bit and third bit is R1′ and R3′, respectively.

In this way, combining section 205 specifies the systematic bits with which the repetition bits are combined, based on the same parity check matrix as used in repetition section 102 in radio communication apparatus 100 of the transmitting side. By this means, even when radio communication apparatus 100 of the transmitting side does not report the positions of systematic bits repeated in radio communication apparatus 100 of the transmitting side, it is nevertheless possible to acquire 12-bit data having the same data length (i.e. received data after combining) as the LDPC codeword generated in radio communication apparatus 100 of the transmitting side.

In this way, according to the present embodiment, in a case where there are a plurality of systematic bits having the same column degree in a parity check matrix, systematic bits and repetition bits are combined in order from the systematic bit corresponding to the variable node connected with the check node having the smallest row degree in the parity check matrix, so that it is possible to compensate for the likelihoods of systematic bits having little effect on likelihood improving by combining bits. By this means, it is possible to make the likelihoods of all systematic bits high and perform LDPC decoding. Therefore, according to the present embodiment, it is possible to maximize the effect of improving error rate performances by repetition with an LDPC code.

Further, according to the present embodiment, the radio communication apparatus of the receiving side is able to specify the systematic bits with which repetition bits are combined, even when the radio communication apparatus of the transmitting side does not report the positions of systematic bits to repeat, and therefore the radio communication apparatus of the receiving side can nevertheless perform LDPC decoding that maximizes the effect of improving error rate performances by repetition, without increasing overhead with report information.

### Embodiment 2

A case will be explained with the present embodiment below where there are a plurality of systematic bits having the same column degree and row degree in a parity check matrix.

Now, the operations of repetition section 102 according to the present embodiment will be explained below. A case will be explained here where one systematic bit is repeated.

Generally, in LDPC encoding, column degree of a parity bit is smaller than column degree of a systematic bit in a parity check matrix. That is, in a Tanner graph, a variable node corresponding to a parity bit holds connections with a smaller number of check nodes than a variable node corresponding to a systematic bit. A variable node corresponding to a parity bit has the smaller number of times to pass likelihoods between variable nodes via check nodes than a variable node corresponding to a systematic bit, and therefore the effect of updating likelihoods in a variable node corresponding to a parity bit is less. By this means, in the case where there are a plurality of systematic bits having the same column degree and row degree in a parity check matrix, a variable node connected with a check node holding connections with the larger number of variable nodes receives fewer likelihoods via check nodes with which variable nodes are connected, and therefore the effect of updating likelihoods for the variable node is less. That is, in the ease where a variable node is repeated, it is preferable to compensate and improve likelihoods by repeating a variable node connected with a check node holding connections with the larger number of variable nodes corresponding to parity bits with priority. That is, the effect of likelihood improving by repetition is more significant at a variable node connected with the check node holding connection with the largest number of variable nodes corresponding to parity bits.

Then, in a case where there are a plurality of systematic bits having the same column degree and row degree, repetition section 102 repeats the systematic bits in order from the systematic bit corresponding to the variable node connected with the check nodes holding connections with the largest number of variable nodes corresponding to parity bits.

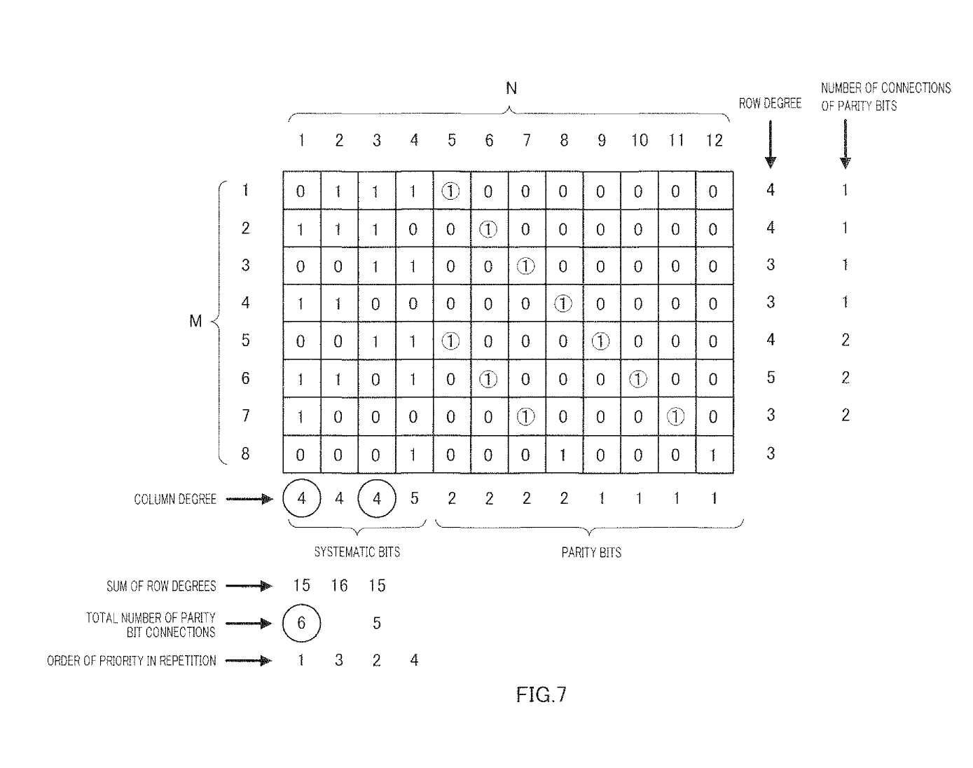

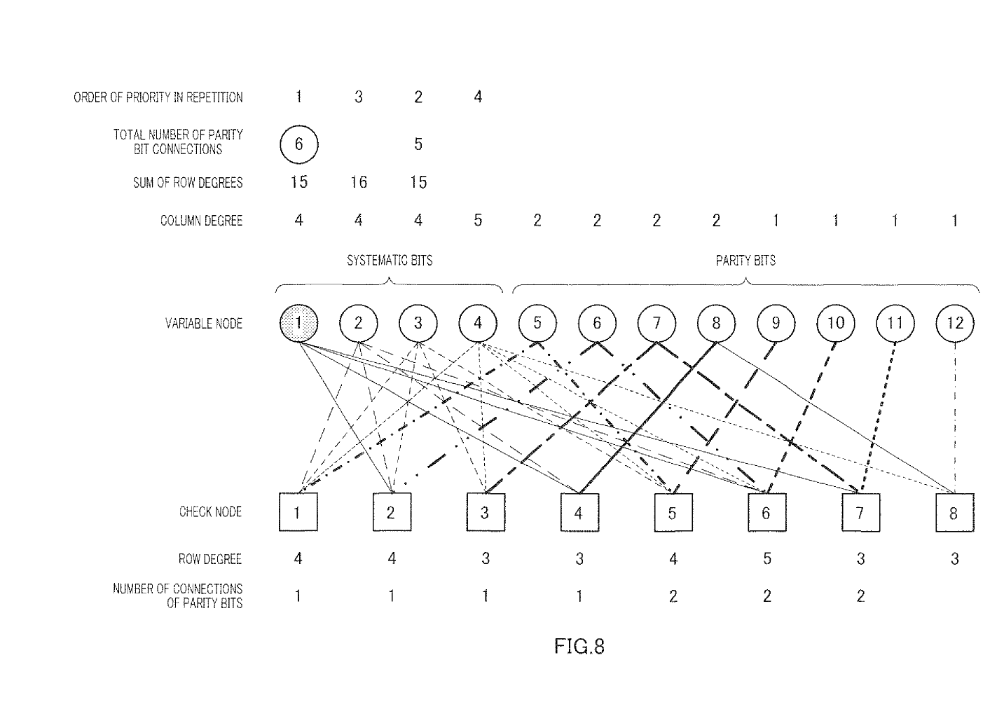

Now, a specific explanation will be given below. In the following description, LDPC encoding is performed using the parity check matrix shown in FIG. 7. FIG. 8 shows a Tanner graph corresponding to the parity check matrix in FIG. 7.

Similar to Embodiment 1, repetition section 102 first extracts systematic bits corresponding to the first to third column (variable node 1 to variable node 3) as repetition candidates based on the parity check matrix shown in FIG. 7. The order of priority in repetition at this time is that the first column and third column are the first, the second column the third.

However, while the number of systematic bits to repeat in repetition section 102 is one, the number of columns of the first priority is two, the first column and third column, and therefore it is necessary to determine which of the first column and third column to make the repetition candidate.

Then, repetition section 102 extracts the systematic bits to be repetition candidates in order from the systematic bit corresponding to the variable node connected with the check node holding connections with the largest number of variable nodes corresponding to parity bits. That is, repetition section 102 compares the number of connections with variable node 5 to variable node 12 between check nodes which variable node 1 to 3 are connected with, in the Tanner graph shown in FIG. 8. The check nodes which variable node 1 is connected with are check node 2, check node 4, check node 6 and check node 7, and check node 2 is connected with variable node 6 amongst variable node 5 to variable node 12. Likewise, check node 4 is connected with variable node 8, check node 6 connected with variable node 6 and variable node 10, and check node 7 is connected with variable node 7 and variable node 11. Further, the check nodes which variable node 3 is connected with are check node 1, check node 2, check node 3, and check node 5, and check node 1 is connected with variable node 5 amongst variable node 5 to variable node 12. Likewise, check node 2 is connected with variable node 6, check node 3 connected with variable node 7, and check node 5 is connected with variable node 5 and variable node 9. Consequently, repetition section 102 compares the total number of connections, six, with variable nodes corresponding to parity bits in check node 2, check node 4, check node 6 and check node 7 which variable node 1 is connected with, and the total number of connections, five, with variable nodes corresponding to parity bits in check node 1, check node 2, check node 3 and check node 5 which variable node 3 is connected with.

Then, repetition section 102 extracts the systematic bits to be repetition candidates in order from the variable node connected with the check node holding connections with the largest number of parity bits. Consequently, repetition section 102 makes variable node 1 a repetition candidate of a higher priority than variable node 3. Therefore, as shown in FIGS. 7 and 8, the order of priority in repetition for systematic bits is that variable node 1 (first column) is the first, variable node 3 the second, variable node 2 the third and variable node 4 the fourth.

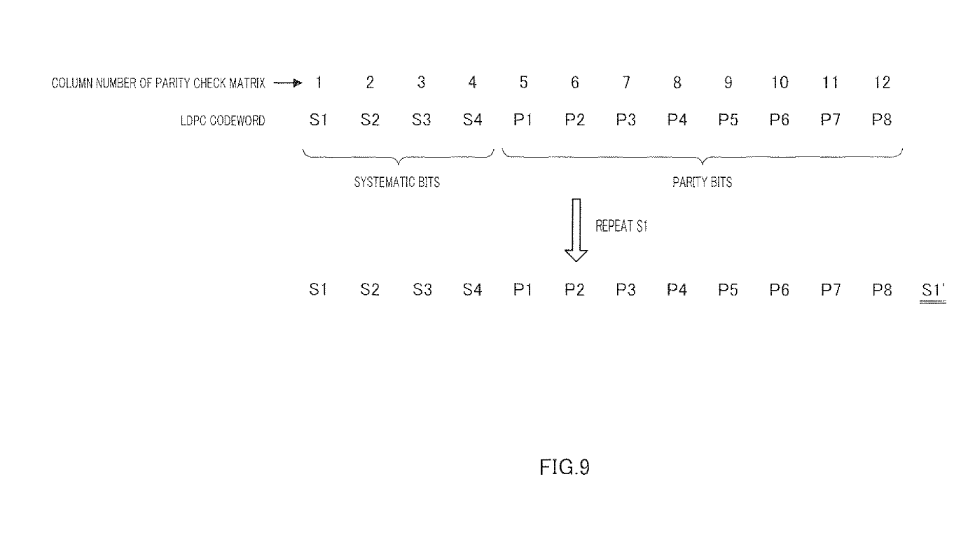

Then, given that the number of systematic bits to repeat is one, repetition section 102 repeats systematic bit Si corresponding to variable node 1, to generate repetition bit S1′ in a 12-bit LDPC codeword composed of four systematic bits of S1 to S4 and eight parity bits of P1 to P8, according to the order of priority in repetition, as shown in FIG. 9. Repetition bit S1′ is the same as systematic bit S1. Repetition section 102 inserts S1′ in the tail of the LDPC codeword, that is, behind parity bit P8. By this means, repetition section 102 can obtain a 13-bit LDPC codeword composed of four systematic bits of S1 to S4, eight parity bits of P1 to P8 and one repetition hit of S1′.

Further, combining section 205 of radio communication apparatus 200 (FIG. 5) of the receiving side specifies the systematic bit with which the repetition bit is combined in the same method as in repetition section 102.

In this way, according to the present embodiment, a systematic bit is repeated in order from the systematic bit corresponding to the variable node connected with the check nodes holding connections with the largest number of variable nodes corresponding to parity bits, so that, even when there are a plurality of systematic bits having the same column degree and row degree in a parity check matrix, it is possible to maximize the effect of improving error rate performances by repetition.

### Embodiment 3

The present embodiment is different from Embodiment 1 in repeating parity bits.

Then, in a case where there are a plurality of parity bits having the same column degree in a parity bit matrix, repetition section 102 according to the present embodiment repeats party bits in order from the parity bit corresponding to the variable node connected with the check node having the smallest row degree (the check node holding connections with the smallest number of variable nodes).

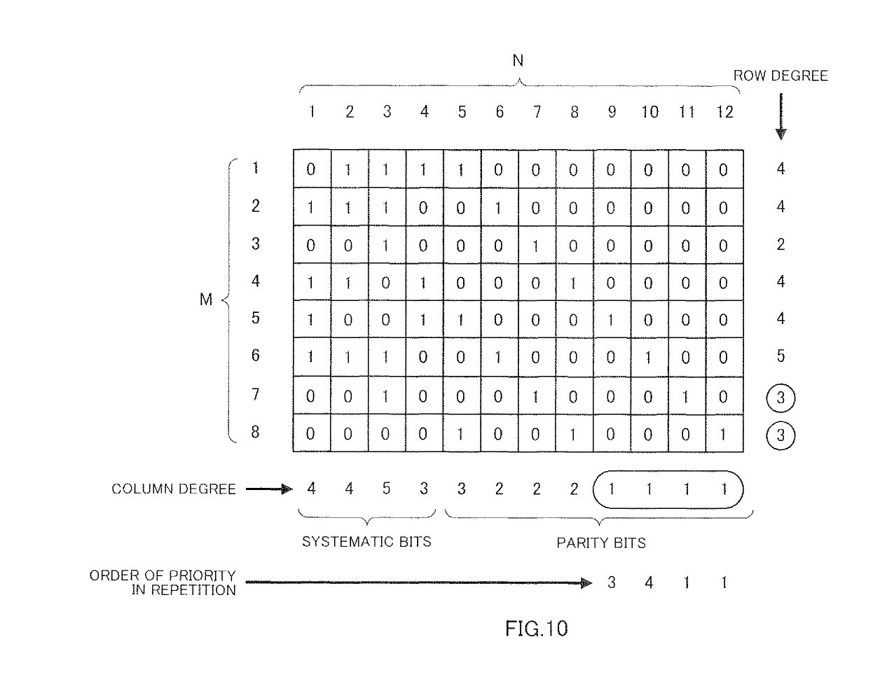

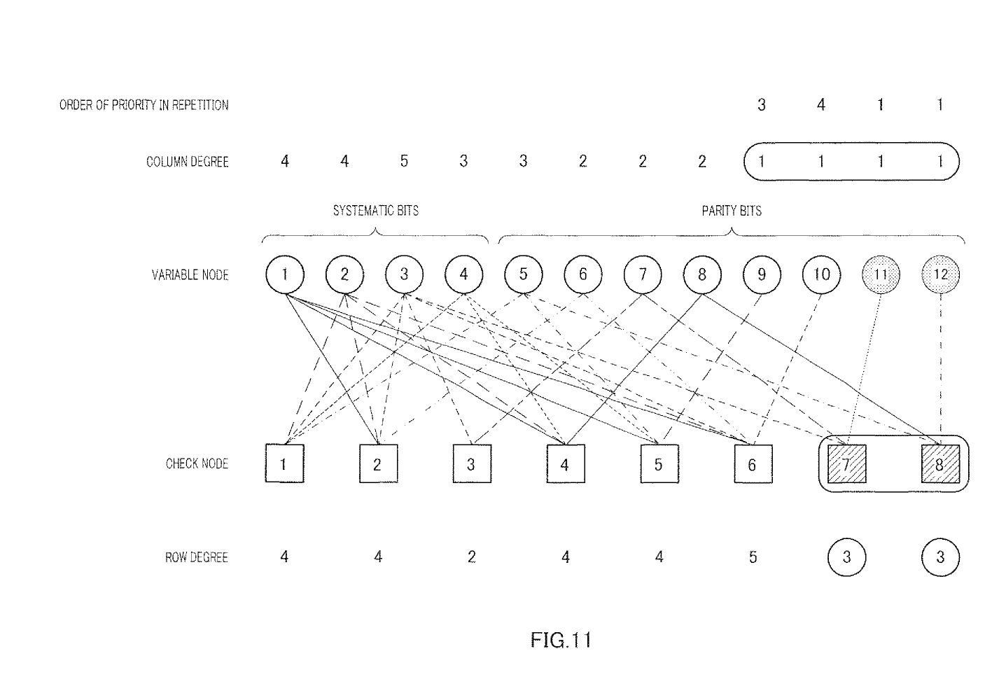

Now, the operations of repetition section 102 according to the present embodiment will be explained below. A case will be explained here where two parity bits are repeated. In the following description, LDPC encoding is performed using the parity check matrix shown in FIG. 10. FIG. 11 shows a Tanner graph corresponding to the parity check matrix in FIG. 10.

Similar to Embodiment 1, repetition section 102 first extracts the ninth to twelfth column (variable node 9 to variable node 12 in the Tanner graph shown in FIG. 11), as repetition candidates, amongst the fifth to twelfth column (variable node 5 to variable node 12) corresponding to parity bits based on the parity check matrix shown in FIG. 10.

However, while the number of parity bits to repeat in repetition section 102 is two, the number of columns to extract, that is, the number of variable nodes holding connections with the same number of check nodes, is four.

Then, repetition section 102 extracts the parity bits to be repetition candidates in order from the parity bit corresponding to the variable node connected with the check node having the smallest row degree of the parity check matrix (i.e. the parity bit corresponding to the variable node connected with the check node holding connections with the smallest number of variable nodes).

That is, amongst the ninth column to twelfth column in the parity check matrix shown in FIG. 10, repetition section 102 compares the row degree of the fifth row, four, in which a 1 is located in the ninth column (i.e. the number of connections, four, with variable nodes in check node 5 which variable node 9 is connected with), the row degree of the sixth row, five, in which a 1 is located in the tenth column (i.e. the number of connections, five, with variable nodes in check node 6 which variable node 10 is connected with), the row degree of the seventh row, three, in which a 1 is located in the eleventh column (i.e. the number of connections, three, with variable nodes in check node 7 which variable node 11 is connected with), and the row degree of the eighth row, three, in which a 1 is located in the twelfth column (i.e. the number of connections, three, with variable nodes in check node 8 which variable node 12 is connected with). That is, repetition section 102 compares the number of connections with variable nodes between check nodes connected with each variable node amongst variable node 9 to variable node 12 in the Tanner graph shown in FIG. 11. Then, repetition section 102 extracts the parity bits to be repetition candidates in order from the column corresponding to the smallest row degree (i.e. from the variable node connected with the check node holding connections with the smallest number of variable nodes).

Consequently, the order of priority in repetition amongst the ninth to twelfth column (variable node 9 to variable node 12) is that, as shown in FIGS. 10 and 11, the eleventh column (variable node 11) and twelfth column (variable node 12) are the first, the ninth column (variable node 9) the third, the tenth column (variable node 10) the fourth.

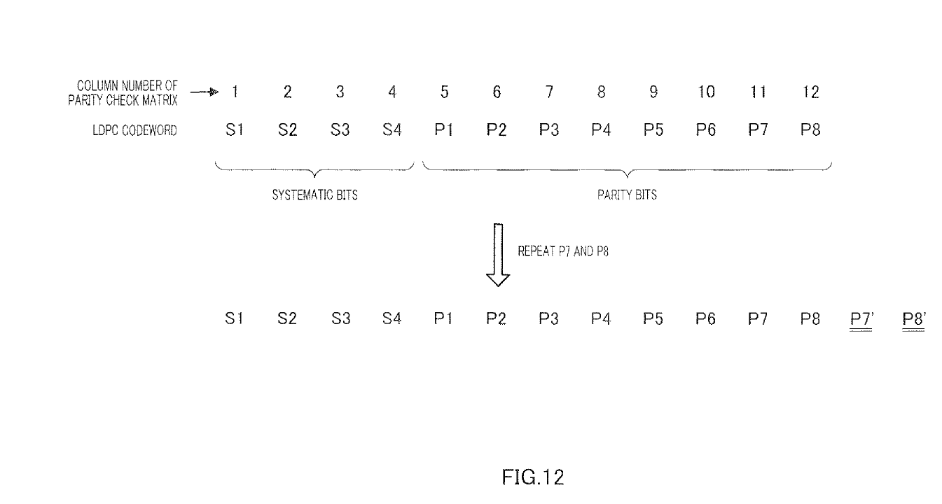

Then, given that the number of parity bits to repeat is two, repetition section 102 repeats parity bit P7 in the eleventh column (variable node 11) and parity bit P8 in the twelfth column (variable node 12) in a 12-bit LDPC codeword composed of four systematic bits of S1 to S4 and eight parity bits of P1 to P8, to generate repetition bits P7′ and P8′ as shown in FIG. 12, according to the order of priority in repetition. Repetition bit P7′ is the same as parity bit P7, and repetition bit P8′ is the same as parity bit P8. Repetition section 102 inserts P7′ and P8′ in the tail of the LDPC codeword, that is, behind parity bit P8 in order from P7′ to P8′. By this means, repetition section 102 can obtain a 14-bit LDPC codeword composed of four systematic bits of S1 to S4, eight parity bits of P1 to P8 and two repetition bits of P7′ and P8′.

Further, combining section 205 of radio communication apparatus 200 (FIG. 5) of the receiving side specifies the parity bits with which the repetition bits are combined in the same method as in repetition section 102.

In this way, according to the present embodiment, repetition makes it possible to compensate likelihoods of parity bits having little effect on likelihood improving by an LDPC code. By this means, it is possible to increase effect of updating likelihoods indirectly for systematic bits connected with the parity bits via check nodes by raising the likelihoods of parity bits. Therefore, according to the present embodiment, it is possible to perform LDPC encoding that maximizes the effect of improving error rate performances by repetition.

### Embodiment 4

The present embodiment is different from Embodiment 2 in repeating parity bits.

Then, in a case where there are a plurality of parity bits having the same column degree and row degree, repetition section 102 repeats parity bits in order from the parity bit corresponding to the variable node connected with the check node holding connections with the largest number of variable nodes corresponding to parity bits.

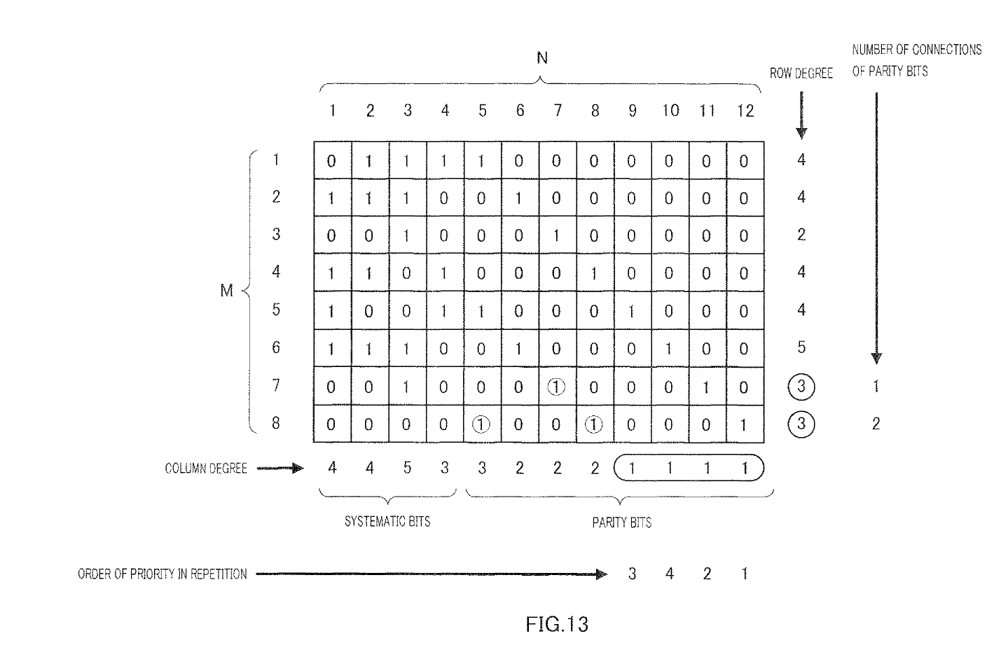

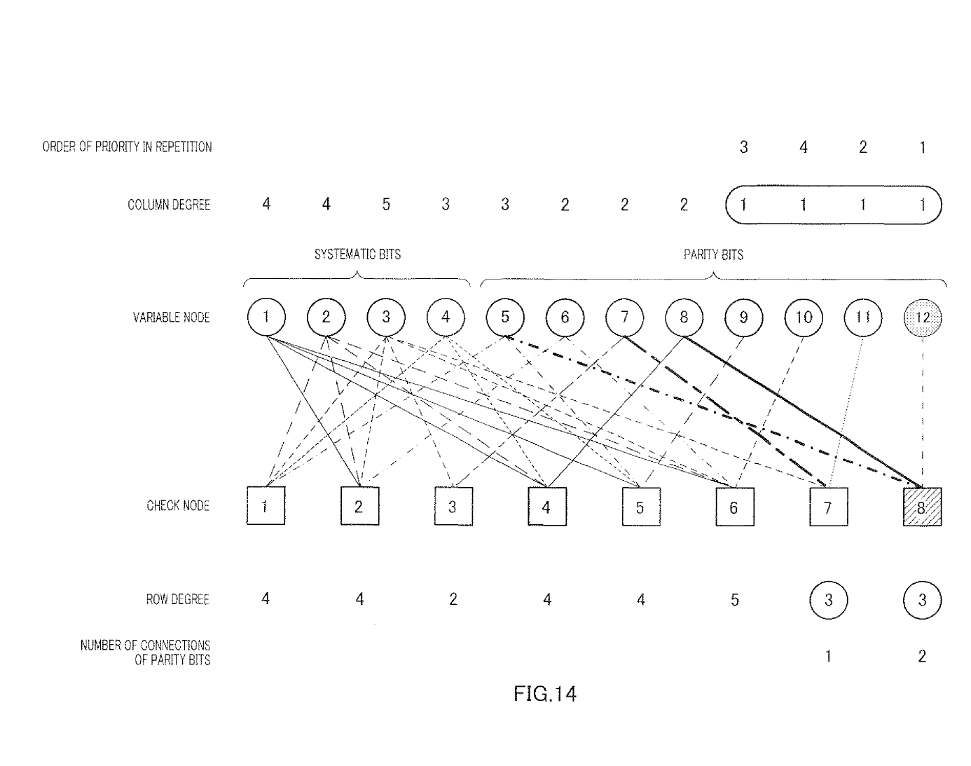

Now, the operations of repetition section 102 according to the present embodiment will be explained below. A case will be explained here where one parity bit is repeated. In the following description, LDPC encoding is performed using the parity check matrix shown in FIG. 13. FIG. 14 shows a Tanner graph corresponding to the parity check matrix in FIG. 13.

Similar to Embodiments 1 and 2, repetition section 102 first extracts the parity bits corresponding to the ninth to twelfth column (variable node 9 to variable node 12) as repetition candidates, based on the parity check matrix shown in FIG. 13. The order of priority in repetition at this time is that the eleventh column and twelfth column are the first, the ninth column the third, and the tenth column the fourth.

However, while the number of systematic bits to repeat in repetition section 102 is one, the number of columns of the first priority is two, the eleventh column and twelfth column, and therefore it is necessary to determine which of the eleventh column and twelfth column to make the repetition candidate.

Then, repetition section 102 extracts the parity bits to be repetition candidates in order from the parity bit corresponding to the variable node connected with the check node holding connections with the largest number of variable nodes corresponding to parity bits. That is, repetition section 102 compares the number of connections with variable node 5 to variable node 12 between check nodes which variable node 11 and variable node 12 are connected with, in the Tanner graph shown in FIG. 14. The check node which variable node 11 is connected with is check node 7, and check node 7 is connected with variable node 7 besides variable node 11, amongst variable node 5 to variable node 12. The check node which variable node 12 is connected with is check node 8, and check node 8 is connected with variable node 5 and variable node 8 besides variable node 12, amongst variable node 5 to variable node 12. Consequently, repetition section 102 compares the number of connections, one, with variable nodes corresponding to parity bits in check node 7 which variable node 11 is connected with, and the number of connections, two, with variable nodes corresponding to parity bits in check node 8 which variable node 12 is connected with.

Then, repetition section 102 extracts the parity bits to be repetition candidates in order from the variable node connected with the check node holding connections with the largest number of parity bits. Consequently, repetition section 102 makes variable node 12 a repetition candidate of a higher priority than variable node 11. Consequently, as shown in FIGS. 13 and 14, the order of priority in repetition for parity bits is that variable node 12 (twelfth column) is the first, variable node 11 (eleventh column) the second, variable node 9 (ninth column) the third and variable node 10 (tenth column) the fourth.

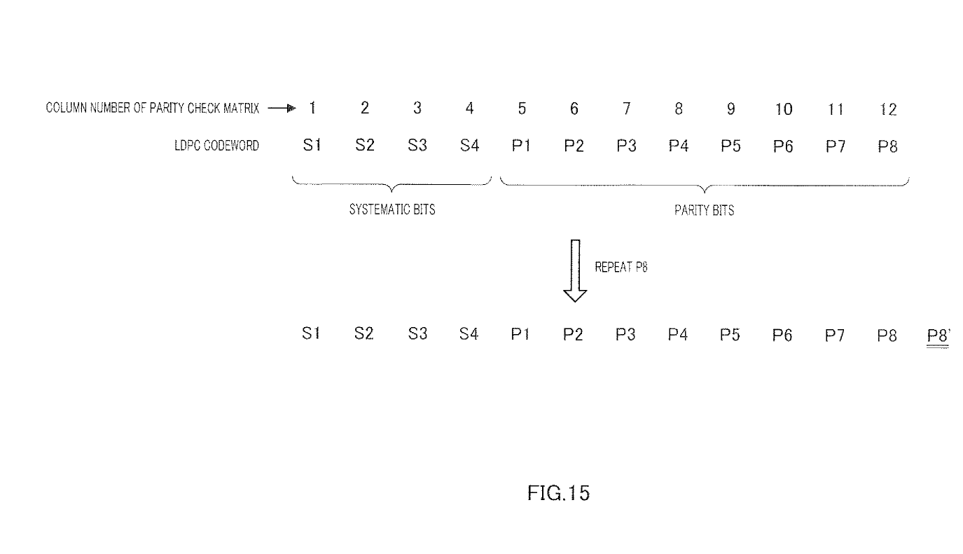

Then, given that the number of parity bits to repeat is one, repetition section 102 repeats parity bit P8 corresponding to variable node 12, to generate repetition bit P8′ in a 12-bit LDPC codeword composed of four systematic bits of S1 to S4 and eight parity bits of P1 to P8, according to the order of priority in repetition, as shown in FIG. 15. Repetition bit P8′ is the same as parity bit P8.

Repetition section 102 inserts P8′ in the tail of the LDPC codeword, that is, behind parity bit P8. By this means, repetition section 102 can obtain a 13-bit LDPC codeword composed of four systematic bits of S1 to S4, eight parity bits of P1 to P8 and one repetition bit of P8′.

Further, combining section 205 of radio communication apparatus 200 (FIG. 5) of the receiving side specifies the parity bit with which the repetition bit is combined in the same method as in repetition section 102.

In this way, according to the present embodiment, it is possible to provide the same advantage as in Embodiment 3 even when there are a plurality of parity bits having the same column degree and row degree in a parity check matrix.

Embodiments of the present invention have been explained.

Further, although cases have been explained with the embodiments where the present invention is implemented in a FDD (Frequency Division Duplex) system, the present invention may be implemented in a TDD (Time Division Duplex) system. In the TDD system, the correlation between uplink channel characteristics and downlink channel characteristics is very high, so that radio communication apparatus 100 of the transmitting side can estimate received quality in radio communication apparatus 200 of the receiving side using signals from radio communication apparatus 200 of the receiving side. Therefore, in the TDD system, radio communication apparatus 200 of the receiving side may not report channel quality by CQI and radio communication apparatus 100 of the transmitting side may estimate channel quality.

Further, the parity check matrices shown in FIGS. 2, 7, 10 and 13 are examples, and parity check matrices utilized to implement the present invention are not limited to the parity check matrices shown in FIGS. 2, 7, 10 and 13.

Further, the coding rate set in control section 110 of radio communication apparatus 100 of the transmitting side is not limited to coding rates to he determined according to channel quality, and, may be a fixed rate.

Further, although, with the embodiments, SINR is estimated as channel quality, the SNR, SIR, CINR, received power, interference power, bit error rate, throughput, MCS (Modulation and Coding Scheme) that achieves a predetermined error rate, and so on may be estimated as channel quality. Further, a CQI may be referred to as “CSI (Channel State Information).”

Further, in mobile communication systems, radio communication apparatus 100 of the transmitting side may be provided in a radio communication base station apparatus and radio communication apparatus 200 of the receiving side may be provided in a radio communication mobile station apparatus. Further, radio communication apparatus 100 of the transmitting side may be provided in a radio communication mobile station apparatus and radio communication apparatus 200 of the receiving side may be provided in a radio communication base station apparatus. By this means, it is possible to realize a radio communication base station apparatus and radio communication mobile station apparatus providing an advantage as described above.

Further, a radio communication mobile station apparatus may be referred to as a “UE,” and a radio communication base station apparatus may be referred to as a “Node B,”

Further, although cases have been described with the above embodiment as examples where the present invention is configured by hardware, the present invention can also be realized by software.

Each function block employed in the description of each of the aforementioned embodiments may typically be implemented as an LSI constituted by an integrated circuit.

These may be individual chips or partially or totally contained on a single chip. “LSI” is adopted here but this may also be referred to as “IC,” “system LSI,” “super LSI,” or “ultra LSI” depending on differing extents of integration.

Further, the method of circuit integration is not limited to LSIs, and implementation using dedicated circuitry or general purpose processors is also possible. After LSI manufacture, utilization of a programmable FPGA (Field Programmable Gate Array) or a reconfigurable processor where connections and settings of circuit cells within an LSI can be reconfigured is also possible.

Further, if integrated circuit technology comes out to replace LSI's as a result of the advancement of semiconductor technology or a derivative other technology, it is naturally also possible to carry out function block integration using this technology. Application of biotechnology is also possible.

The disclosure of Japanese Patent Application No. 2007-030648, filed on Feb. 9, 2007, including the specification, drawings and abstract, is incorporated herein by reference in its entirety.

### INDUSTRIAL APPLICABILITY

The present invention is applicable to, for example, mobile communication systems.

1. A radio communication apparatus of a transmitting side, comprising:
an encoding section that performs low density parity check encoding for a transmission bit sequence using a parity check matrix, to acquire a codeword composed of systematic bits and parity bits; and
a repetition section that repeats a bit in the codeword in order from a bit of a smallest column degree in the parity check matrix, and, when there are a plurality of bits of a same column degree, repeats the bit in order from the bit corresponding to a variable node connected with a check node of a smallest row degree in the parity check matrix.

2. The radio communication apparatus according to claim 1, wherein the repetition section repeats a number of bits determined based on a difference between a first coding rate in the low density parity check encoding and a second coding rate according to channel quality.

3. The radio communication apparatus according to claim 1, wherein, when there are a plurality of bits of the same column degree and the same row degree, the repetition section repeats each of the plurality of bits in order from the bit corresponding to the variable node connected with the check node holding connections with the largest number of the variable nodes corresponding to the parity bits.

4. The radio communication apparatus according to claim 1, wherein the repetition section repeats a systematic bit in the codeword,

5. The radio communication apparatus according to claim 1, wherein the repetition section repeats a parity bit in the codeword.

6. A radio communication apparatus of a receiving side, comprising:
a combining section that combines a bit in first received data and a corresponding repetition bit to generate second received data in order from a bit of a smallest column degree in a parity check matrix in low density parity check encoding, and, when there are a plurality of bits of a same column degree, combines the bit in the first received data and the corresponding repetition bit to generate the second received data in order from the bit corresponding to a variable node connected with a check node of a smallest row degree in the parity check matrix; and
a decoding section that performs low density parity check decoding using the parity check matrix for the second received data, to acquire a received bit sequence.

7. The radio communication apparatus according to claim 1, wherein the radio communication apparatus comprises a radio communication base station apparatus or a radio communication mobile station apparatus.

8. The radio communication apparatus according to claim 6, wherein the radio communication apparatus comprises a radio communication base station apparatus or a radio communication mobile station apparatus.

9. A repetition method in a codeword composed of systematic bits and parity bits and obtained by low density parity check encoding using a parity check matrix, the method comprising:
repeating a bit in the codeword in order from a bit of a smallest column degree in the parity check matrix, and, when there are a plurality of bits of a same column degree, repeating the bit in order from the bit corresponding to a variable node connected with a check node of a smallest row degree in the parity check matrix.
